(19) United States
(12) Patent Application Publication
(10) Pub. No.: US 2025/0048856 A1
(43) Pub. Date: Feb. 6, 2025

(54) DISPLAY PANEL AND DISPLAY DEVICE

(71) Applicant: Wuhan Tianma Microelectronics Co., Ltd., Wuhan Hubei (CN)

(72) Inventor: Zhaofeng REN, Wuhan (CN)

(73) Assignee: Wuhan Tianma Microelectronics Co., Ltd., Wuhan Hubei (CN)

(21) Appl. No.: 18/927,138

(22) Filed: Oct. 25, 2024

(30) Foreign Application Priority Data
Apr. 24, 2024 (CN) 202410508565.4

(51) Int. Cl. H10K 59/124; H10K 59/131; H10K 59/35

(52) U.S. Cl. CPC H10K 59/124; H10K 59/131; H10K 59/35

(57) ABSTRACT

A display panel and a display device are provided. The display panel includes a substrate, a pixel circuit layer, a light-emitting element layer and a dielectric structure. The pixel circuit layer includes multiple pixel circuits and multiple signal wires, and the multiple signal wires include at least one first signal wire. The light-emitting element layer includes multiple light-emitting elements. A light-emitting element includes a first electrode; and in a first direction, at least one first electrode at least partially overlaps the first signal wire. In the first direction, the dielectric structure is located between the first signal wire and the first electrode, and at least partially overlaps the first signal wire and the first electrode; at a first temperature T1, the dielectric structure has a first dielectric constant ε1, and at a second temperature T2, the dielectric structure has a second dielectric constant ε2; and (T1−T2)(ε1−ε2)>0.

### CROSS-REFERENCE TO RELATED APPLICATION

This application claims priority to Chinese Patent Application No. 202410508565.4, filed on Apr. 24, 2024, the disclosure of which is incorporated herein by reference in its entirety.

### TECHNICAL FIELD

Embodiments of the present disclosure relate to the field of display technology and, in particular, to a display panel and a display device.

### BACKGROUND

Thin film transistors (TFT) are widely used as switching elements in various display devices. The thin film transistors in the pixel circuit are the main elements for driving the sub-pixels to emit light, and their stability has an important influence on the display effect of the display device. In the related art, there is a problem of poor stability of thin film transistors, which leads to unstable output current of the pixel circuits, adversely affects the display luminance of the sub-pixels, and causes poor display effect.

### SUMMARY

In view of this, a display panel and a display device are provided according to the present disclosure to improve stability of output current of the pixel circuit and improve display effect of the display panel.

In a first aspect, a display panel is provided according to embodiments of the present disclosure, which includes a substrate, a pixel circuit layer, a light-emitting element layer and a dielectric structure.

The pixel circuit layer is arranged on one side of the substrate and includes multiple pixel circuits and multiple signal wires, where the multiple signal wires include at least one first signal wire.

The light-emitting element layer is arranged on a side of the pixel circuit layer away from the substrate and includes multiple light-emitting elements. A light-emitting element of the multiple light-emitting elements includes a first electrode, and the first electrode is electrically connected to the pixel circuit; in a first direction, at least one first electrode at least partially overlaps the first signal wire, and the first direction is the thickness direction of the display panel.

In the first direction, the dielectric structure is located between the first signal wire and the first electrode, and at least partially overlaps the first signal wire and the first electrode; at a first temperature T1, the dielectric structure has a first dielectric constant ε1, and at a second temperature T2, the dielectric structure has a second dielectric constant ε2; where, (T1−T2)(ε1−ε2)>0.

In a second aspect, a display device is provided according to embodiments of the present disclosure, which includes the display panel described in the first aspect of the present disclosure.

### BRIEF DESCRIPTION OF DRAWINGS

FIG. 1 is a schematic diagram of the structure of a display panel provided in an embodiment of the present disclosure;

FIG. 2 is a schematic sectional view of the structure along A-A′ of FIG. 1;

FIG. 3 is a schematic enlarged view of the structure at B of FIG. 2;

FIG. 4 is a schematic sectional view of a partial structure of a display panel provided in an embodiment of the present disclosure;

FIG. 5 is a schematic sectional view of a partial structure of another display panel provided in an embodiment of the present disclosure;

FIG. 6 is a schematic sectional view of a partial structure of still another display panel provided in an embodiment of the present disclosure;

FIG. 7 is a schematic diagram of the circuit structure of a pixel circuit provided in an embodiment of the present disclosure;

FIG. 8 is a partial layout diagram of a display panel provided in an embodiment of the present disclosure;

FIG. 9 is a partial layout diagram of another display panel provided in an embodiment of the present disclosure;

FIG. 10 is a schematic sectional view of a partial structure of yet another display panel provided in an embodiment of the present disclosure;

FIG. 11 is a schematic diagram of a partial structure of a display panel provided in an embodiment of the present disclosure;

FIG. 12 is a schematic diagram of a partial structure of another display panel provided in an embodiment of the present disclosure;

FIG. 13 is a schematic diagram of a partial structure of still another display panel provided in an embodiment of the present disclosure;

FIG. 14 is a schematic sectional view of a partial structure of still another display panel provided in an embodiment of the present disclosure;

FIG. 15 is a schematic diagram of a partial structure of yet another display panel provided in an embodiment of the present disclosure;

FIG. 16 is a schematic diagram of a partial structure of yet another display panel provided in an embodiment of the present disclosure; and

FIG. 17 is a schematic diagram of the structure of a display device provided in an embodiment of the present disclosure.

### DETAILED DESCRIPTION

The present disclosure is described in detail hereinafter in conjunction with drawings and embodiments. It is to be understood that the specific embodiments set forth here are merely intended to illustrating rather than limiting the present disclosure. Additionally, it is to be noted that, for ease of description, only part, not all, of the structures related to the present disclosure are illustrated in the drawings.

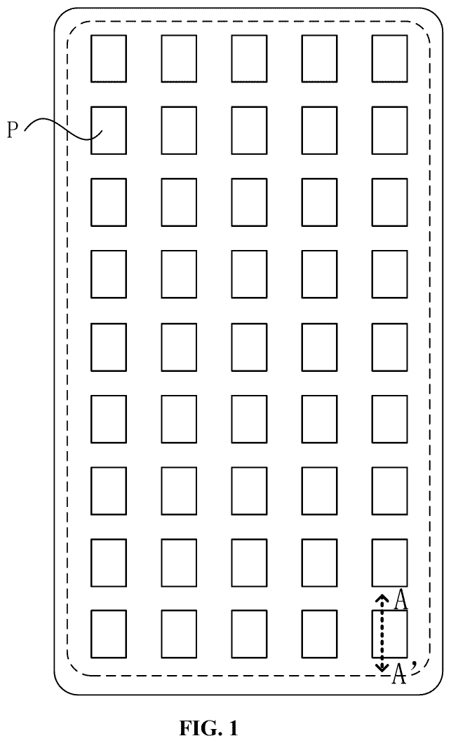

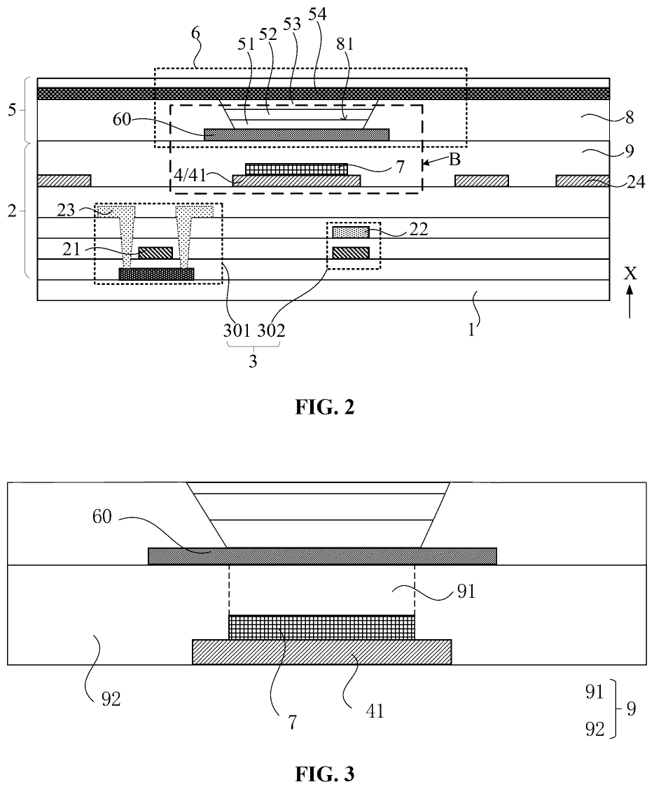

FIG. 1 is a schematic diagram of the structure of a display panel provided in an embodiment of the present disclosure, and FIG. 2 is a schematic sectional view of the structure along A-A′ of FIG. 1. Referring to FIG. 1 and FIG. 2, in an embodiment of the present disclosure, the display panel includes: a substrate 1; a pixel circuit layer 2, in an embodiment, the pixel circuit layer 2 is arranged on a side of the substrate 1 and includes multiple pixel circuits 3 and multiple signal wires 4, and the multiple signal wires 4 include at least one first signal wire 41; a light-emitting element layer 5, in an embodiment, the light-emitting element layer 5 is arranged on a side of the pixel circuit layer 2 away from the substrate 1 and includes multiple light-emitting elements 6, the light-emitting element 6 includes a first electrode 60, and the first electrode 60 is electrically connected to the pixel circuit 3; in a first direction X, at least one first electrode 60 at least partially overlaps the first signal wire 41, and the first direction X is the thickness direction of the display panel; and a dielectric structure 7, in an embodiment, in the first direction X, the dielectric structure 7 is located between the first signal wire 41 and the first electrode 60, and at least partially overlaps each of the first signal wire 41 and the first electrode 60. At a first temperature T1, the dielectric structure 7 has a first dielectric constant E1, and at a second temperature T2, the dielectric structure 7 has a second dielectric constant ε2; where, (T1−T2)(ε1−ε2)>0.

As shown in FIG. 1 and FIG. 2, the display panel includes the substrate 1, the pixel circuit layer 2, the light-emitting element layer 5 and other structures. In an embodiment, the substrate 1 can be a rigid substrate or a flexible substrate, which is not limited in embodiments of the present disclosure. The pixel circuit layer 2 and the light-emitting element layer 5 are sequentially arranged on a side surface of the substrate 1, and the pixel circuits 3 cooperate with the signal wires 4 in the pixel circuit layer 2 to drive the light-emitting elements 6 in the light-emitting element layer 5 to emit light. A pixel circuit 3 and a corresponding light-emitting element 6 driven by the pixel circuit 3 constitute a sub-pixel P, and the display panel may include multiple sub-pixels P arranged in an array.

In an embodiment, the pixel circuit 3 may include an output terminal, the output terminal is electrically connected to the first electrode 60 of the light-emitting element 6, at least part of the signal wire 4 is electrically connected to the pixel circuit 3, and the signal wire 4 is used to transmit the required electrical signal to the pixel circuit 3. Under the control of multiple electrical signals, the pixel circuit 3 generates a driving current, and the driving current is transmitted to the first electrode 60. It should be noted that the electrical connection relationships between the pixel circuit 3 and the first electrode 60, and between the signal wire 4 and the pixel circuit 3 are not shown in FIG. 1 and FIG. 2. The display panel in the embodiment of the present disclosure may be a light-emitting diode display panel, for example, an organic light-emitting diode display panel or a micro light-emitting diode display panel, but is not limited thereto. In the embodiment of the present disclosure, the organic light-emitting diode display panel is taken as an example for explanation.

Exemplarily, referring to FIG. 2, a pixel definition layer 8 may be provided on a surface of the pixel circuit layer 2 on a side facing away from the substrate 1, and the pixel definition layer 8 includes multiple openings 81, and the multiple openings 81 define multiple light-emitting element setting regions, and at least part of the first electrode 60 is located in the light-emitting element setting region. The light-emitting element layer 5 may further include a first carrier transport layer 51, a light-emitting layer 52, a second carrier transport layer 53 and a second electrode layer 54, but is not limited thereto. The first carrier transport layer 51, the light-emitting layer 52, the second carrier transport layer 53, and the second electrode layer 54 may be located sequentially on a side of the first electrode 60 facing away from the pixel circuit layer 2. The first electrode 60, the first carrier transport layer 51, the light-emitting layer 52, the second carrier transport layer 53, and the second electrode layer 54 located in the same light-emitting element setting region constitute a light-emitting element 6. In an embodiment, the first carrier may be a hole, the second carrier may be an electron, or the first carrier may be an electron, and the second carrier may be a hole. When the first electrode 60 and the second electrode layer 54 receive the corresponding electrical signal, the first carrier is injected into the first carrier transport layer 51, and the second carrier is injected into the second carrier transport layer 53, and the first carrier and the second carrier are recombined in the light-emitting layer 52 and emit light. Apparently, the structure of the practical light-emitting element layer 5 is not limited to this. In practical applications, the person skilled in the art can design the structure of the light-emitting element layer 5 according to requirements.

In an embodiment, the pixel circuit 3 may include a thin film transistor 301 and a capacitor 302. The thin film transistor 301 includes a driving transistor, and the driving transistor is configured to generate a driving current. The driving current generated by the driving transistor is transmitted to the first electrode 60 through the output terminal of the pixel circuit 3. The inventor of the present disclosure found in the study that the thin film transistor 301 has a certain temperature sensitivity. Within a certain temperature range, when the ambient temperature of the thin film transistor 301 increases, the output current of the thin film transistor 301 increases. Taking the driving transistor as an example, in the display process of the display panel, as the display time increases, the display panel generates more heat, which may cause the driving current generated by the driving transistor to increase, and the driving current transmitted to the light-emitting element 6 to increase, causing the luminance of light emitted by the light-emitting element 6 to increase, and then the problem of partial or overall excessive brightness occurs, thus adversely affecting the normal display of the display panel.

Based on the above problems, with reference to FIG. 2, it is proposed in the present disclosure that the multiple signal wires 4 include at least one first signal wire 41, and in the thickness direction X of the display panel, the first signal wire 41 overlaps at least one first electrode 60. The two structures overlapping in a certain direction mentioned in the present disclosure means that projections of the two structures in this direction overlap. The first signal wire 41 can be a signal wire 4 that transmits any electrical signal, which is not limited in the present disclosure. In addition, the dielectric structure 7 is further provided in the display panel, and the dielectric structure 7 is arranged between the first signal wire 41 and the first electrode 60. In the first direction X, there are overlapping regions between the dielectric structure 7, the first signal wire 41 and the first electrode 60, and the first signal wire 41 and the first electrode 60 are spaced apart by at least the dielectric structure 7.

It can be understood that the first signal wire 41 and the first electrode 60 are both conductive materials, for example, conductive metal or transparent conductive material. The first electrode 60 and the first signal wire 41 whose projections overlap can be used as two plates of a capacitor to form a capacitor structure. The dielectric structure 7 is an insulating dielectric material, and the dielectric structure 7 between the first electrode 60 and the first signal wire 41 is the dielectric of the capacitor structure. It is worth mentioning that further definition is made in the embodiment of the present disclosure that the dielectric constant temperature coefficient of the dielectric structure 7 can change with the change of temperature, that is, at least at two different temperatures, the dielectric structure 7 has different dielectric constants, and the dielectric constant of the dielectric structure 7 changes positively with the ambient temperature. At a higher temperature, the dielectric structure 7 has a larger dielectric constant temperature; at a lower temperature, the dielectric structure 7 has a smaller dielectric constant temperature coefficient.

With this setting, when the working environment temperature of the thin film transistor 301 increases, the dielectric constant temperature of the dielectric structure 7 increases accordingly. According to the capacitance calculation formula of the capacitor: C=εS/4πkd, (where C is the capacitance, ε is the dielectric constant of the dielectric, S is the facing area of the two plates, d is the distance between the two plates, and k is the electrostatic force constant), the capacitance C is proportional to the dielectric constant ε of the dielectric between the two plates of the capacitor. When the dielectric constant of the dielectric structure 7 increases, the capacitance of the capacitor structure formed by the first signal wire 41 and the first electrode 60 increases, the amount of charge that can be stored between the two increases, so that part of the driving current transmitted from the pixel circuit 3 to the first electrode 60 can be stored, offsetting the part of the driving current increased due to temperature rising, ensuring the stability of the driving current transmitted from the pixel circuit 3 to the light-emitting element 6, reducing the influence of temperature on the luminance of light emitted by the light-emitting element 6, solving the over-bright problem of the display panel caused by heating, and improving the display effect of the display panel.

Exemplarily, when the first temperature T1 is higher than the second temperature T2, the first dielectric constant ε1 of the dielectric structure 7 is greater than the second dielectric constant ε2; when the first temperature T1 is lower than the second temperature T2, the first dielectric constant ε1 of the dielectric structure 7 is less than the second dielectric constant 82. It should be noted that the above-mentioned first temperature T1 and second temperature T2 do not refer to two fixed temperature values, but refer to two relative temperature values; accordingly, the first dielectric constant ε1 and the second dielectric constant 82 do not refer to two fixed dielectric constant values, but refer to two relative dielectric constant values.

The specific material of the dielectric structure 7 is not limited in the embodiment of the present disclosure, which can be set by the person skilled in the art according to practical requirements. For example, for the dielectric structure 7, a polymer material with a positive dielectric constant temperature coefficient can be used, which includes but is not limited to an epoxy resin-based material, or an acrylonitrile-styrene-acrylate (ASA) material.

In addition, the numbers of the first signal wires 41 and dielectric structures 7 to be arranged are not limited in the embodiment of the present disclosure. The person skilled in the art may arrange part or all of first signal wires 41 and dielectric structures 7 correspondingly overlapping the first electrodes 60 according to practical requirements. Exemplarily, in some embodiments, since the heat dissipation effect in the middle of the display panel is relatively poor, the heat accumulation there is relatively serious, and the possibility of occurrence of over-bright problem caused by heating is relatively high, the first signal wires 41 and dielectric structures 7 may be arranged only in a part of the middle region of the display panel to offset the part of the driving current increased of the pixel circuit 3 due to temperature rising in this region, thereby ensuring display uniformity.

In the embodiment of the present disclosure, the first signal wires 41 and the dielectric structures 7 are arranged in the display panel, so that in the first direction X, the overlapped first electrode 60 and first signal wire 41 form a capacitor structure, the dielectric structure 7 serves as a dielectric between the two plates of the capacitor structure, and the dielectric structure 7 is configured to have a larger dielectric constant temperature coefficient at a higher temperature and a smaller dielectric constant temperature coefficient at a lower temperature. When the dielectric constant of the medium structure 7 increases with the increase of temperature, the capacitance of the capacitor structure formed by the first signal wire 41 and the first electrode 60 increases, and the amount of charge that can be stored between the first signal wire 41 and the first electrode 60 increases, so that part of the driving current transmitted from the pixel circuit 3 to the first electrode 60 can be stored, offsetting the part of the driving current increased due to temperature rising, ensuring the stability of the driving current transmitted from the pixel circuit 3 to the light-emitting element 6, reducing the influence of temperature on the luminance of light emitted by the light-emitting element 6, solving the over-bright problem of the display panel caused by heating, and improving the display effect of the display panel.

Optionally, reference may be made to FIG. 2. In an optional embodiment, in the first direction X, a film layer in which the first electrode 60 is located and a film layer in which the first signal wire 41 is located are spaced apart by an insulating layer 9, and the dielectric structure 7 at least partially overlaps the insulating layer 9, and the dielectric constant temperature coefficient αε1 of the dielectric structure 7 is greater than the dielectric constant temperature coefficient αε2 of the insulating layer 9.

As shown in FIG. 2, the first electrode 60 and the first signal wire 41 are respectively located in different conductive film layers, and the film layers where the first electrode 60 and the first signal wire 41 are located are electrically insulated by the insulating layer 9. In this embodiment, in the first direction X, the dielectric structure 7 can be stacked with part of the insulating layer 9 between the first electrode 60 and the first signal wire 41. In this arrangement, the dielectric between the capacitor structure formed by the first electrode 60 and the first signal wire 41 includes the dielectric structure 7 and the insulating layer 9.

Further, in this embodiment, the dielectric constant temperature coefficient αε1 of the dielectric structure 7 may be set to be greater than the dielectric constant temperature coefficient αε2 of the insulating layer 9. The dielectric constant temperature coefficient αε refers to the relative average change rate of the dielectric constant of a material when the temperature rises by 1° C. within a certain temperature range. Within a certain temperature range, the larger the dielectric constant temperature coefficient as of the material, the greater the increase in the dielectric constant with temperature rising. In this embodiment, the dielectric structure 7 is set to have a large dielectric constant temperature coefficient, and the insulating layer 9 has a small dielectric constant temperature coefficient. The dielectric constant of the dielectric structure 7 changes with temperature more, and the dielectric constant of the insulating layer 9 changes with temperature less. In this way, it can be ensured that when the temperature rises, the dielectric constant of the dielectric between the first electrode 60 and the first signal wire 41 increases, the charge storage capacity is enhanced, and the dielectric constant of the insulating layer 9 in other areas is prevented from being affected by temperature.

Materials of the insulating layer 9 and the dielectric structure 7 are not limited in the embodiments of the present disclosure. The insulating layer 9 can be prepared by any insulating layer 9 material in the conventional display panel, including but not limited to a polyimide material; the dielectric structure 7 can be selected from the epoxy resin-based material and/or the ASA material as mentioned above, as long as it can ensure that the dielectric constant temperature coefficient αε1 of the dielectric structure 7 is greater than the dielectric constant temperature coefficient αε2 of the insulating layer 9.

Optionally, FIG. 3 is a schematic enlarged view of the structure at B of FIG. 2, reference can be made to FIG. 2 and FIG. 3, in an optional embodiment, the insulating layer 9 includes a first part 91, and the first part 91 is located on a side of the dielectric structure 7 away from the substrate 1.

In an embodiment, in the embodiment shown in FIG. 2 and FIG. 3, the insulating layer 9 includes the first part 91 and a second part 92 which are provided integrally, the first part 91 refers to a portion located between the first electrode 60 and the first signal wire 41 and overlapping the dielectric structure 7, the second part 92 is other portions excluding the first part 91, and the second part 92 surrounds at least part of the first part 91. In FIG. 3, the first part 91 and the second part 92 are divided by a dotted line, and there is actually no dividing line between the two. In the first direction X, the first signal wire 41, the dielectric structure 7, the first part 91 and the first electrode 60 can be arranged in a stacked manner, the dielectric structure 7 is in contact with the first signal wire 41, and the first part 91 is located between the first electrode 60 and the dielectric structure 7.

In this way, the dielectric structure 7 can be first prepared on the side of the first signal wire 41 away from the substrate 1, then a whole layer of insulating layer 9 can be prepared on the side of the dielectric structure 7 away from the first signal wire 41, the first part 91 of the insulating layer 9 covers the surface of the dielectric structure 7 on a side facing away from the first signal wire 41, and the second part 92 covers at least part of the side wall of the dielectric structure 7. The insulating layer 9 can play a flattening role to ensure the flatness of the first electrode 60 in subsequent preparation.

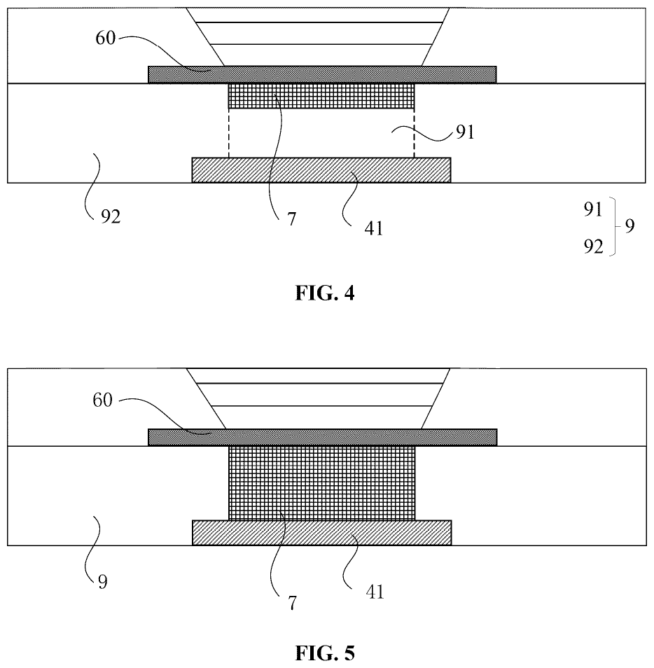

FIG. 4 is a schematic sectional view of a partial structure of a display panel provided in an embodiment of the present disclosure. In the embodiment shown in FIG. 4, the insulating layer 9 still includes the first part 91, which is different from the embodiment shown in FIG. 3 in that the dielectric structure 7 is located on a side of the first part 91 away from the first signal wire 41, and the dielectric structure 7 is in contact with the first electrode 60. In this case, a whole layer of insulating layer 9 can be prepared on the side of the first signal wire 41 away from the substrate 1, and then a dielectric structure 7 can be prepared on the side of the insulating layer 9 away from the first signal wire 41.

Apparently, in other embodiments not shown, in the first direction X, the dielectric structure 7 can be located in the insulating layer 9, that is, upper and lower surfaces of the dielectric structure 7 in the first direction X are covered by the insulating layer 9, which is not described in detail further in the embodiment of the present disclosure.

Optionally, FIG. 5 is a schematic sectional view of a partial structure of another display panel provided in an embodiment of the present disclosure. In the embodiment shown in FIG. 5, in the first direction X, the dielectric structure 7 and the insulating layer 9 do not overlap, that is, in the first direction X, the dielectric structure 7 fills at least part of the region between the first electrode 60 and the first signal wire 41, and the space between the film layer in which the first electrode 60 is located and the film layer in which the first signal wire 41 is located may further include the insulating layer 9, and the insulating layer 9 can cover the sidewalls of the dielectric structure 7 and fill the region where the dielectric structure 7 is not provided between the film layer in which the first electrode 60 is located and the film layer in which the first signal wire 41 is located.

In addition, the overlapping area between the first electrode 60 and the first signal wire 41, the overlapping area between the dielectric structure 7 and the first electrode 60 (or the first signal wire 41), the thickness of the dielectric structure 7 and other parameters are not limited in the embodiment of the present disclosure. According to the capacitance calculation formula, the above parameters will also affect the capacitance between the first electrode 60 and the first signal wire 41. In practical applications, the person skilled in the art can set the above parameters according to requirements.

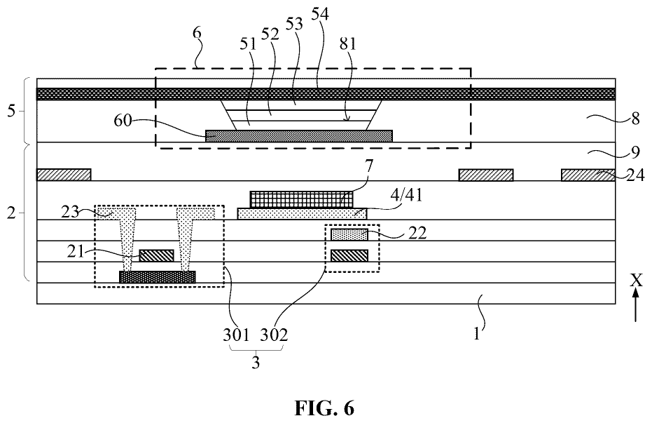

Optionally, FIG. 6 is a schematic sectional view of a partial structure of still another display panel provided in an embodiment of the present disclosure. With reference to FIG. 2 and FIG. 6, the pixel circuit layer 2 may include a first metal layer 21, a capacitor metal layer 22, a second metal layer 23 and a third metal layer 24 arranged in the first direction X, and the third metal layer 24 is located between the second metal layer 23 and the film layer in which the first electrode 60 is located. The first signal wire 41 is located in at least one of the first metal layer 21, the capacitor metal layer 22, the second metal layer 23 or the third metal layer 24.

In an embodiment, the pixel circuit layer 2 includes multiple metal layers arranged in a stacked manner, and any two adjacent metal layers are insulated from each other. The multiple metal layers are configured to form multiple pixel circuits 3 and multiple signal wires 4. The first metal layer 21 may be located on one side of the substrate 1, the capacitor metal layer 22 is located on a side of the first metal layer 21 away from the substrate 1, the second metal layer 23 is located on a side of the capacitor metal layer 22 away from the first metal layer 21, the third metal layer 24 is located on a side of the second metal layer 23 away from the capacitor metal layer 22, and the film layer in which the first electrode 60 is located is located on a side of the third metal layer 24 away from the second metal layer 23.

In an embodiment of the present disclosure, the first signal wire 41 may be formed in at least one metal layer in the pixel circuit layer 2, which is not limited and described in detail in the embodiment of the present disclosure. The embodiments shown in FIG. 2 and FIG. 6 respectively show that the first signal wire 41 is located in different metal layers. Apparently, the film layer in which the first signal wire 41 is formed is not limited to this practically. In the process of practical application, the person skilled in the art may design the film layer in which the first signal wire 41 is located according to the practical situation.

Optionally, referring to FIG. 2, in some embodiments, the first signal wire 41 may be located in the third metal layer 24.

In the first direction X, the third metal layer 24 is close to the film layer in which the first electrode 60 is located. In other words, the third metal layer 24 may be a metal layer located on the side of the first electrode 60 close to the substrate 1 and closest to the first electrode 60 in the display panel. The third metal layer 24 may be used to form the first signal wire 41, so that the capacitor structure formed by the first electrode 60 and the first signal wire 41 has a large capacitance, and plays a strong charge storage role. In this setting, the dielectric structure 7 may be stacked with the insulating layer 9 between the film layer in which the third metal layer 24 is located and the film layer in which the first electrode 60 is located.

In addition, it is known to the person skilled in the art that structures such as the thin film transistor 301 and the capacitor 302 in the pixel circuit 3 are generally located in the metal film layers close to the substrate 1, for example, the first metal layer 21, the capacitor metal layer 22 and the second metal layer 23. There are more conductive structures arranged in the first metal layer 21, the capacitor metal layer 22 and the second metal layer 23, and fewer conductive structures arranged in the third metal layer 24. The first signal wire 41 is formed by using the third metal layer 24, so that the layout space of the first signal wire 41 is large, which facilitates designing of parameters such as the shape and size of the capacitor structure formed by the first electrode 60 and the first signal wire 41.

As shown in FIG. 6, in some other embodiments, the first signal wire 41 may be located in the second metal layer 23. In this case, the dielectric structure 7 may be located in the insulating layer 9 between the third metal layer 24 and the film layer in which the first electrode 60 is located, and/or, the dielectric structure 7 may be located in the insulating layer 9 between the second metal layer 23 and the third metal layer 24. FIG. 6 exemplarily shows that the dielectric structure 7 is located in the insulating layer 9 between the second metal layer 23 and the third metal layer 24, the location of the dielectric structure 7 is not limited to this.

The specific connection relationship between the first signal wire 41 and the pixel circuit 3, or the electrical signal transmitted by the first signal wire 41, is not limited in the embodiment of the present disclosure, and can be set by the person skilled in the art according to practical requirements.

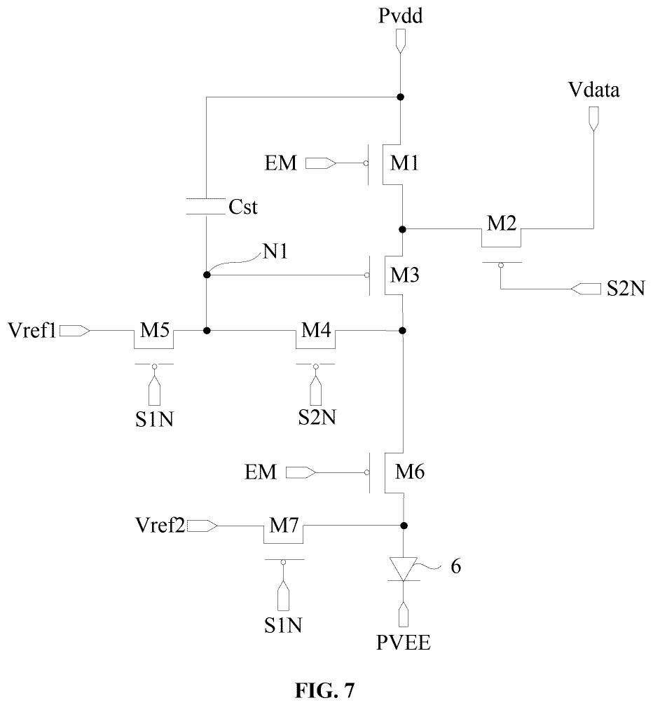

FIG. 7 is a schematic diagram of the circuit structure of a pixel circuit provided in an embodiment of the present disclosure. The pixel circuit 3 shown in FIG. 7 includes seven thin film transistors and one capacitor, which is not limited thereto in practice, the pixel circuit 3 is only used as an example for explanation in this embodiment. The signal wiring in the display panel may include a first scanning signal line, a second scanning signal line, a light emission control signal line, a first power supply voltage signal line, a first reference voltage signal line, a second reference voltage signal line and a data signal line. The driving process of the pixel circuit 3 provided in the embodiment of the present disclosure is introduced hereinafter in conjunction with FIG. 7.

As shown in FIG. 7, the pixel circuit 3 may include a first light emission control transistor M1, a data writing transistor M2, a driving transistor M3, a threshold compensation transistor M4, a first reset transistor M5, a second light emission control transistor M6, a second reset transistor M7 and a storage capacitor Cst. A gate of the first light emission control transistor M1 is connected to the light emission control signal line to receive a light emission control signal Em transmitted by the light emission control signal line, a source of the first light emission control transistor M1 is connected to a first power supply voltage signal line to receive a first power supply voltage signal Pvdd transmitted by the first power supply voltage signal line, a drain of the first light emission control transistor M1 is electrically connected to a drain of the data writing transistor M2 and a source of the driving transistor M3. A gate of the data writing transistor M2 is connected to the second scanning signal line to receive a second scanning signal S2N transmitted by the second scanning signal line, and a source of the data writing transistor M2 is connected to the data signal line to receive a data signal Vdata transmitted by the data signal line. A gate of the driving transistor M3 is connected to a first plate of the storage capacitor Cst, a drain of the threshold compensation transistor M4 and a drain of the first reset transistor M5, and a drain of the driving transistor M3 is connected to a source of the threshold compensation transistor M4 and a source of the second light emission control transistor M6. A second plate of the storage capacitor Cst is connected to the first power supply voltage signal line. A gate of the threshold compensation transistor M4 is connected to the second scanning signal line. A gate of the first reset transistor M5 is connected to the first scanning signal line, to receive a first scanning signal SIN transmitted by the first scanning signal line, a source of the first reset transistor M5 is connected to a first reference signal line, to receive a first reference voltage signal Vref1 transmitted by the first reference signal line. A gate of the second light emission control transistor M6 is connected to the light emission control signal line, a drain of the second light emission control transistor M6 is connected to the light-emitting element 6 and a drain of the second reset transistor M7. A gate of the second reset transistor M7 is connected to the first scanning signal line, a source of the second reset transistor M7 is connected to a second reference signal line to receive a second reference voltage signal Vref2 transmitted by the second reference signal line.

The working principle of the pixel circuit 3 can be roughly described as follows. In an initialization stage, the first reset transistor M5 is turned on according to the first scanning signal SIN transmitted by the first scanning signal line, and the first reference voltage signal Vref1 is written into the first node N1 (the first plate of the storage capacitor Cst), and since the gate of the driving transistor M3 is connected to the first node N1, the first reference voltage signal Vref1 is written into the gate of the driving transistor M3 to complete the initialization of the driving transistor M3. In this stage, the second reset transistor M7 can be turned on according to the first scanning signal SIN transmitted by the first scanning signal line, and the second reference voltage signal Vref2 is written into the first electrode of the light-emitting element 6 to initialize the first electrode of the light-emitting element 6. In a data writing stage, the data writing transistor M2 and the threshold compensation transistor M4 are turned on according to the second scanning signal S2N transmitted by the second scanning signal line, and meanwhile the driving transistor M3 is also turned on. The data signal Vdata transmitted by the data signal line is applied to the first node N1 through the data writing transistor M2, the driving transistor M3 and the threshold compensation transistor M4 in sequence, and the storage capacitor Cst stores the voltage of the first node N1. In a light-emitting stage, the first light emission control transistor M1 and the second light emission control transistor M6 are turned on according to the light emission control signal Em transmitted by the light emission control signal line, and meanwhile the driving transistor M3 is also turned on. The first power supply voltage signal Pvdd passes through the first light emission control transistor M1, the driving transistor M3 and the second light emission control transistor M6, and the driving transistor M3 generates a driving current to drive the light-emitting element 6 to emit light.

The above-mentioned first power supply voltage signal Pvdd, the first reference voltage signal Vref1 and the second reference voltage signal Vref2 are generally fixed voltage signals. In this embodiment, the first signal wire can be at least one of the above-mentioned signal lines that transmit fixed voltage signals. Using the signal line that transmits fixed voltage signals as the first signal wire can ensure that the capacitor formed between the first signal wire and the first electrode has a relatively stable capacitance, and avoid the first signal wire from receiving a jump electrical signal which may adversely affect the storage of charge by the capacitor.

In some embodiments, the first signal wire includes a first power supply voltage signal line, and the first power supply voltage signal line is electrically connected to the pixel circuit, and is configured to provide the first power supply voltage signal Pvdd to the pixel circuit.

The connection relationship between the first power supply voltage signal line and the pixel circuit is introduced above and will not be repeated here. Generally, the first power supply voltage signal line is located in the second metal layer and/or the third metal layer, and is close to the first electrode in the first direction. The first power supply voltage signal line transmits a fixed voltage signal, so that the first power supply voltage signal line with the first electrode are used together to form a capacitor structure to ensure that the capacitor structure has a better charge storage effect.

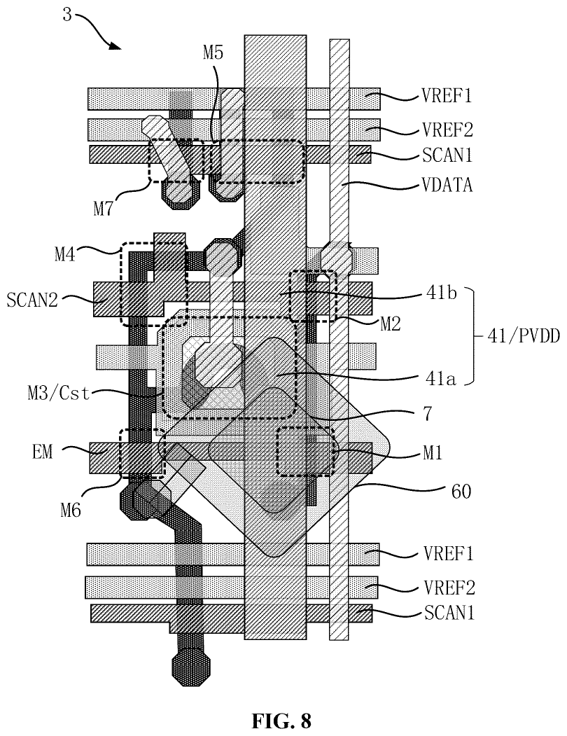

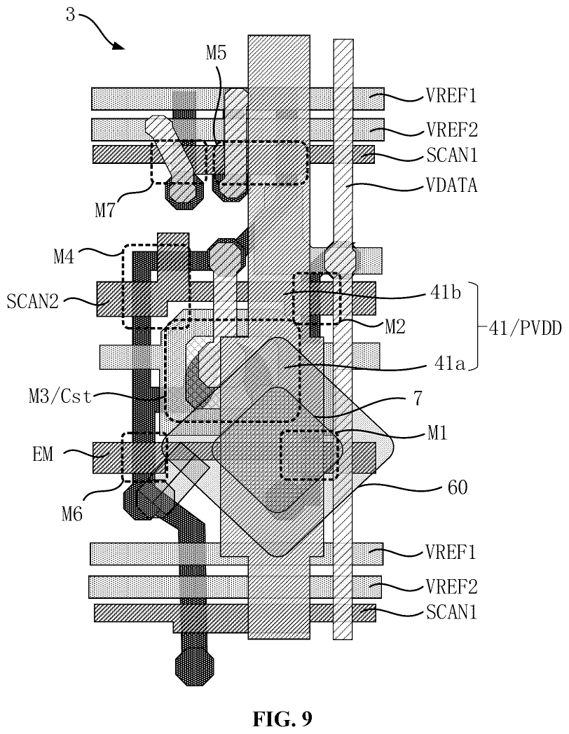

FIG. 8 is a partial layout diagram of a display panel provided in an embodiment of the present disclosure, and FIG. 9 is a partial layout diagram of another display panel provided in an embodiment of the present disclosure. Referring to FIG. 8 and FIG. 9, in an optional embodiment, the first signal wire 41 includes a first wire segment 41a. In the first direction X, the first wire segment 41a and the dielectric structure 7 are both located in the first electrode 60, and the first wire segment 41a overlaps the dielectric structure 7 at least partially.

In order to transmit electrical signals to all sub-pixels in the display panel, in general, the signal wire 4 will extend in a direction parallel to the plane in which the substrate 1 is located. FIG. 8 and FIG. 9 show multiple signal wires in the display panel and multiple thin film transistors and capacitors in the pixel circuit 3. The marked thin film transistors and signal wires correspond to the circuit diagram shown in FIG. 7 above. VDATA corresponds to the data signal line, SCAN1 corresponds to the first scanning signal line, SCAN2 corresponds to the second scanning signal line, EM corresponds to the light emission control signal line, VREF1 corresponds to the first reference voltage signal line, VREF2 corresponds to the second reference voltage signal line, and PVDD corresponds to the first power supply voltage signal line. It is taken as an example that the first signal wire 41 is the first power supply voltage signal line PVDD, as shown in FIG. 8 and FIG. 9, the first power supply voltage signal line PVDD can be extended in the column direction and arranged in the row direction as a whole to transmit the first power supply voltage signal Pvdd to multiple pixel circuits 3.

On this basis, it is proposed in this embodiment that the first signal wire 41 includes a first wire segment 41a, and the first wire segment 41a refers to the part of the first signal wire 41 together with the first electrode 60 forming a capacitor structure. In the first direction X, the first electrode 60 covers the first wire segment 41a and the dielectric structure 7. The first signal wire 41 may further include a second wire segment 41b, and in the first direction X, the second wire segment 41b and the first electrode 60 do not overlap.

The person skilled in the art can set the width of the first wire segment 41a according to practical requirements. The width of the first wire segment 41a affects the overlapping area of the first signal wire 41 and the first electrode 60, and thus affects the magnitude of the capacitance. In the embodiment shown in FIG. 8, the first wire segment 41a and the second wire segment 41b have the same width, and the overlapping area of the first signal wire 41 and the first electrode 60 is small. In the embodiment shown in FIG. 9, the width of the first wire segment 41a is greater than the width of the second wire segment 41b, so that the overlapping area of the first signal wire 41 and the first electrode 60 increases, and the amount of charge that can be stored in the capacitor structure increases.

In addition, the overlapping of the dielectric structure 7 and the first wire segment 41a is not limited in the embodiment of the present disclosure. FIG. 8 and FIG. 9 show that the two partially overlap. In other embodiments, it can be set that the dielectric structure 7 fully overlaps the first wire segment 41a in the first direction X, or, in the first direction X, the first wire segment 41a covers the dielectric structure 7 (that is, the dielectric structure 7 is located within the range of the first wire segment 41a), or, in the first direction X, the dielectric structure 7 covers the first wire segment 41a, which will not be described in detail one by one in the embodiments of the present disclosure, and the person skilled in the art can set it according to practical requirements.

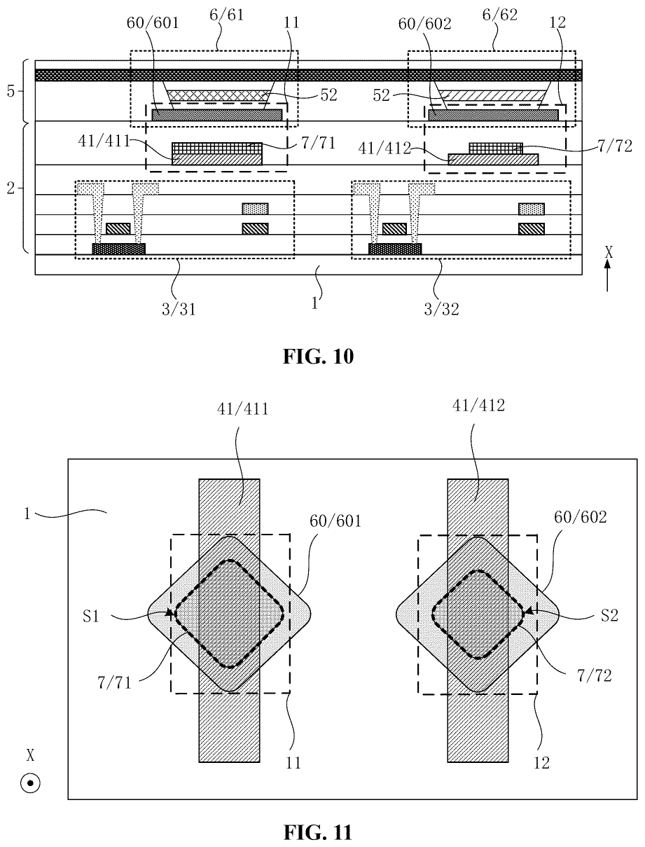

FIG. 10 is a schematic sectional view of a partial structure of yet another display panel provided in an embodiment of the present disclosure. With reference to FIG. 10, in a possible embodiment, the light-emitting element 6 includes a first color light-emitting element 61 and a second color light-emitting element 62, the first electrode 60 of the first color light-emitting element 61 is a first sub-electrode 601, and the first electrode 60 of the second color light-emitting element 62 is a second sub-electrode 602; the pixel circuit 3 includes a first pixel circuit 31 and a second pixel circuit 32, the first pixel circuit 31 is electrically connected to the first sub-electrode 601, and the second pixel circuit 32 is electrically connected to the second sub-electrode 602. The first signal wire 41 includes a first signal sub-wire 411 and a second signal sub-wire 412, and in the first direction X, the first signal sub-wire 411 overlaps at least partially the first sub-electrode 601, and the second signal sub-wire 412 overlaps at least partially the second sub-electrode 602. The first signal sub-wire 411 and the first sub-electrode 601 whose projections overlap constitute a first capacitor structure 11, and the second signal sub-wire 412 and the second sub-electrode 602 whose projections overlap constitute a second capacitor structure 12. The capacitance of the first capacitor structure 11 and the capacitance of the second capacitor structure 12 are different.

The first color light-emitting element 61 and the second color light-emitting element 62 emit light of different colors, and the specific colors of light emission are not limited in this embodiment. The materials of the light-emitting layers 52 in the different color light-emitting elements are different. In FIG. 10, the different filling patterns of the light-emitting layer 52 in the first color light-emitting element 61 and the light-emitting layer 52 of the second color light-emitting element 62 indicate that the materials of the light-emitting layers 52 of the first color light-emitting element 61 and the second color light-emitting element 62 are different. Exemplarily, the colors of light emitted by the light-emitting elements in the current display panel generally include red, green and blue, and the first color and the second color may refer to at least two of the above colors. The pixel circuit driving the first color light-emitting element 61 is the first pixel circuit 31, and the first pixel circuit 31 is connected to the first sub-electrode 601 to transmit the driving current to the first sub-electrode 601, thereby driving the first color light-emitting element 61 to emit light; the pixel circuit driving the second color light-emitting element 62 to emit light is the second pixel circuit 32, and the second pixel circuit 32 is connected to the second sub-electrode 602 to transmit the driving current to the second sub-electrode 602, thereby driving the second color light-emitting element 62 to emit light.

Correspondingly, in the first direction X, the first signal wire 41 overlapping the first sub-electrode 601 is the first signal sub-wire 411, and the first signal wire 41 overlapping the second sub-electrode 602 is the second signal sub-wire 412. It is worth mentioning that in this embodiment, the capacitor structures corresponding to the light-emitting elements of different colors can also be set differently.

In an embodiment, in the first direction X, the overlapping first sub-electrode 601 and first signal sub-wire 411 form the first capacitor structure 11 to serve as two plates of the capacitor, and the overlapping second sub-electrode 602 and second signal sub-wire 412 form the second capacitor structure 12 to serve as two plates of the capacitor. The capacitances of the first capacitor structure 11 and the second capacitor structure 12 are different. The capacitances being different means that the capacitance values of the first capacitor structure 11 and the second capacitor structure 12 are different, that is, the first capacitor structure 11 and the second capacitor structure 12 have different capacities for storing charge.

In the related art, when the display panel works at a higher temperature or the internal temperature of the display panel rises after the display panel works for a long time, color deviation phenomenon will occur. The color deviation phenomenon refers to the deviation of the display color of the display panel from a preset color. For example, the display color of a pixel of the display panel can be obtained by combining the light of the three colors of red, green and blue. The color deviation phenomenon means that when a pixel is displayed, the actual luminance of light emitted by one or more color light-emitting elements is different from the required luminance of light emission, resulting in the color displayed by the pixel being different from the color required to display.

Through research, the inventors found that the driving currents of the driving transistors corresponding to the light-emitting elements of different colors vary with the variation of temperature, and/or the performances of the light-emitting materials used in the light-emitting elements of different colors vary with the variation of temperature, each of which may lead to different luminance deviations of light emitted by the light-emitting elements of different colors in a high temperature environment, thereby causing the above-mentioned color deviation phenomenon.

Based on this, in the embodiment of the present disclosure, the capacitances of the first capacitor structure 11 and the second capacitor structure 12 are set to be different, so that the degrees of adjustments that performed, by the first capacitor structure 11 and the second capacitor structure 12, on the driving current finally output by the pixel circuit are different. With this setting, the capacitances of the first capacitor structure 11 and the second capacitor structure 12 can be designed according to the luminance deviations of the first color light-emitting element 61 and the second color light-emitting element 62 after being heated, so as to use the first capacitor structure 11 to adjust the driving current output by the first pixel circuit 31, and use the second capacitor structure 12 to adjust the driving current output by the second pixel circuit 32, so that the driving current actually received by the first color light-emitting element 61 matches the required luminance of light emitted by the first color light-emitting element 61, and the driving current actually received by the second color light-emitting element 62 matches the required luminance of light emitted by the second color light-emitting element 62. In this manner, the problem of luminance deviation of light emitted by the first color light-emitting element 61 and the second color light-emitting element 62 in a high temperature environment is avoided, solving the problem of color deviation of the display panel when being heated, and enhancing the display effect.

It should be noted that in the embodiment of the present disclosure, the capacitance relationship and specific capacitance values of the first capacitor structure 11 and the second capacitor structure 12 are not limited, which can be designed according to the practical color deviation of the display panel. For example, assuming that the display panel displays a reddish color in a high temperature environment, it means that the red light-emitting element has a greater degree of increase in luminance of light emission in a high temperature environment, and the blue light-emitting element and the green light-emitting element have a smaller degree of increase in luminance of light emission in a high temperature environment. In this case, the capacitance of the capacitor structure corresponding to the red light-emitting element can be set to be greater than the capacitance of the capacitor structure corresponding to the blue light-emitting element (or the green light-emitting element), so that the capacitor structure corresponding to the red light-emitting element can absorb more driving current, and thus the driving current transmitted to the red light-emitting element can be reduced, so as to play a role in reducing the luminance of light emitted by the red light-emitting element, thereby solving the problem of the reddish display color. If the actual display color of the display panel is bluish or greenish, reference may be made the above solution for the same principle to perform a differentiated design of the capacitor structures, which is not described in detail in the embodiment of the present disclosure.

According to the capacitance calculation formula C=εS/4πkd, in addition to the dielectric constant ε of the dielectric, the facing area S, that is, the overlapping area of the two plates of the capacitor and the distance d between the two plates of the capacitor will also affect the capacitance. Based on this, in the embodiments of the present disclosure, the following specific solutions for realizing the differentiated design of the first capacitor structure 11 and the second capacitor structure 12 are proposed.

In some embodiments, the differentiated setting of magnitudes of the capacitances can be realized by differentially setting the dielectric structures corresponding to the first capacitor structure 11 and the second capacitor structure 12.

For example, FIG. 11 is a schematic diagram of a partial structure of a display panel provided in an embodiment of the present disclosure, and FIG. 11 only shows partial structure of the display panel, and does not show the entire film layer structure. Reference may be made to FIG. 10 and FIG. 11, in some embodiments, the dielectric structure 7 includes a first dielectric structure 71 and a second dielectric structure 72; in the first direction X, the first dielectric structure 71 is located between the first signal sub-wire 411 and the first sub-electrode 601, and the first dielectric structure 71 at least partially overlaps the first signal sub-wire 411 and the first sub-electrode 601; and the second dielectric structure 72 is located between the second signal sub-wire 412 and the second sub-electrode 602, and the second dielectric structure 72 at least partially overlaps the second signal sub-wire 412 and the second sub-electrode 602. In the first direction X, an overlapping area of projections the first dielectric structure 71 and the first sub-electrode 601 is S1, and an overlapping area of projections of the second dielectric structure 72 and the second sub-electrode 602 is S2, and S1/S2.

In an embodiment, as shown in FIG. 10 and FIG. 11, the dielectric structure 7 between the two plates of the first capacitor structure 11 can be defined as the first dielectric structure 71, and the dielectric structure 7 between the two plates of the second capacitor structure 12 can be defined as the second dielectric structure 72. In this embodiment, the overlapping area of the first dielectric structure 71 with the corresponding first electrode 60 in the first direction X can be set different from the overlapping area of the second dielectric structure 72 with the corresponding first electrode 60 in the first direction X. It should be noted that in this embodiment, with the overlapping area of projection of the dielectric structure 7 and the first electrode 60 varying, the overlapping area of projection of the dielectric structure 7 with the first signal wire 41 varies.

After the shape design of the first electrode 60 and the first signal wire 41 is completed, the facing area of plates of the capacitor structure formed by the first electrode 60 and the first signal wire 41 is determined. By designing the overlapping area of projections of the dielectric structure 7 and the first electrode 60, the layout area ratio of the dielectric structure 7 in the capacitor structure can be adjusted. The layout area ratio refers to the ratio of the area of overlapping region of projections of the dielectric structure 7, the first electrode 60 and the first signal wire 41 to the facing area of plates in the first direction X. When the ratio of the layout area of the dielectric structure 7 increases, the dielectric constant temperature coefficient of the dielectric between the two plates increases accordingly, that is, the greater the increase in the dielectric constant of the dielectric with the increase in temperature, the greater the capacitance of the capacitor structure after the temperature rises, and vice versa, the smaller the capacitance of the capacitor structure after the temperature drops.

Therefore, in this embodiment, the overlapping area of projections of the first dielectric structure 71 and the first sub-electrode 601 can be set to be different from the overlapping area of projections of the second dielectric structure 72 and the second sub-electrode 602, so as to achieve the differentiated design of capacitances of the first capacitor structure 11 and the second capacitor structure 12. The region framed by the bold dashed line in the left figure of FIG. 11 represents the overlapping region of the first dielectric structure 71 and the first sub-electrode 601, and its area is S1. The region framed by the bold dashed line in the right figure of FIG. 11 represents the overlapping region of the second dielectric structure 72 and the second sub-electrode 602, and its area is S2.

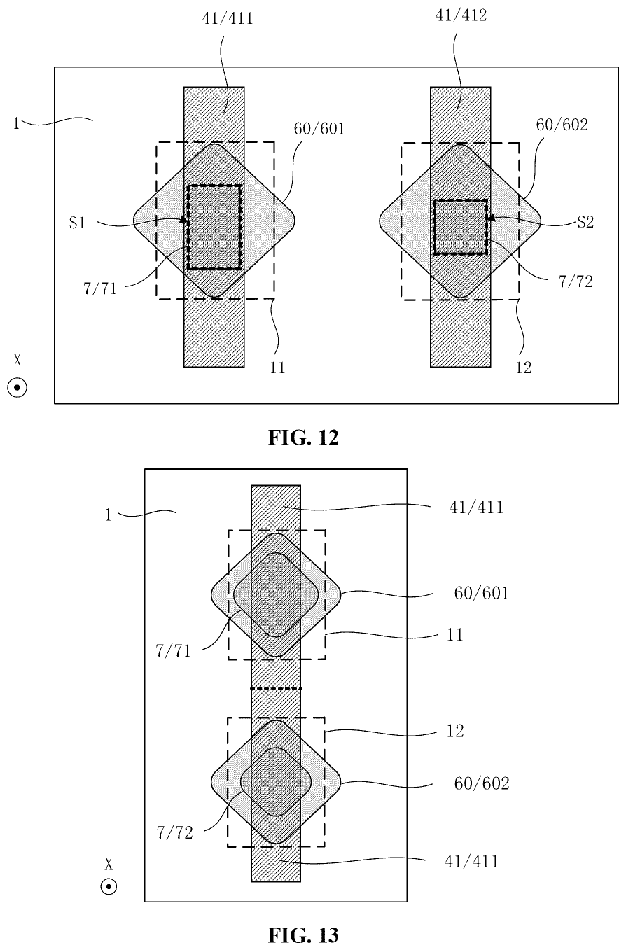

In addition, in FIG. 11, in the row direction, the edge of the first dielectric structure 71 exceeds the edge of the first signal sub-wire 411, and the edge of the second dielectric structure 72 exceeds the edge of the second signal sub-wire 412, and the first dielectric structure 71 has the same shape as the first sub-electrode 601, and the second dielectric structure 72 has the same shape as the second sub-electrode 602, both of which have a rhombus shape, but are not limited thereto. FIG. 12 is a schematic diagram of a partial structure of another display panel provided in an embodiment of the present disclosure. In the embodiment shown in FIG. 12, in the first direction X, the first dielectric structure 71 may be located in the first signal sub-wire 411, and the second dielectric structure 72 may be located in the second signal sub-wire 412, and the first dielectric structure 71 has a different shape from the first sub-electrode 601, and the second dielectric structure 72 has a different shape from the second sub-electrode 602. In practical application, the person skilled in the art can set the shapes of the first signal wire 41, the dielectric structure 7, and the first electrode 60 according to practical requirements, and any varied shapes are within the scope of protection of the technical solution of the embodiment of the present disclosure.

In the embodiments shown in FIG. 11 and FIG. 12, the first signal sub-wire 411 and the second signal sub-wire 412 are two first signal wires 41 arranged in the row direction, and this arrangement corresponds to the situation where the first color light-emitting element and the second color light-emitting element are arranged in the row direction. FIG. 13 is a schematic diagram of a partial structure of still another display panel provided in an embodiment of the present disclosure. In the embodiment shown in FIG. 13, the first signal sub-wire 411 and the second signal sub-wire 412 may refer to different parts of the same first signal wire 41, and this arrangement corresponds to the situation where the first color light-emitting element and the second color light-emitting element are arranged in the column direction. The embodiment of the present disclosure does not limit the arrangement of the first color light-emitting element and the second color light-emitting element in the display panel. When the arrangement of the first color light-emitting element and the second color light-emitting element varies, the arrangement of the first signal sub-wire 411, the second signal sub-wire 412, the first dielectric structure 71, the second dielectric structure 72, the first sub-electrode 601 and the second sub-electrode 602 can be adaptively adjusted.

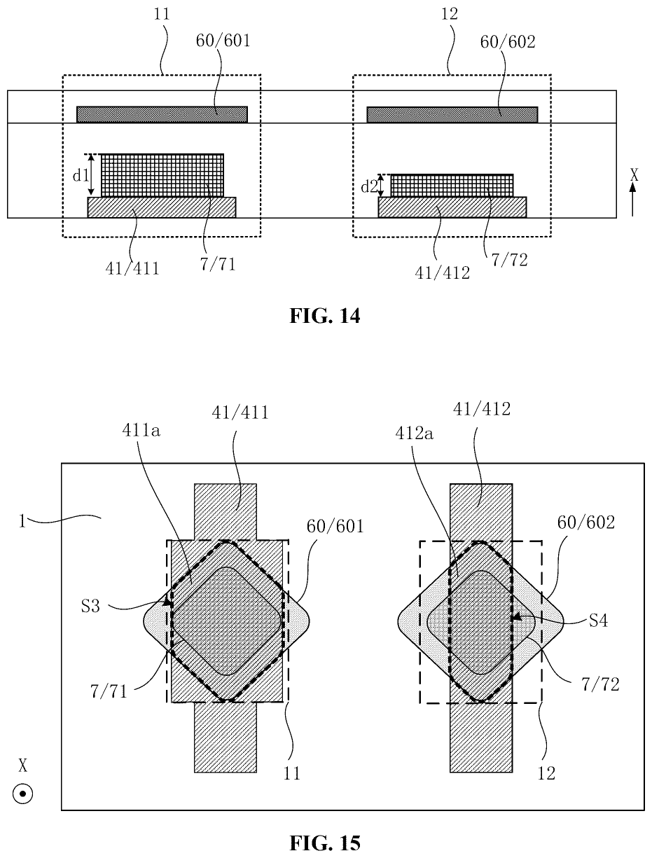

For example, FIG. 14 is a schematic sectional view of a partial structure of still another display panel provided in an embodiment of the present disclosure. Referring to FIG. 14, in other embodiments, the dielectric structure 7 may still include a first dielectric structure 71 and a second dielectric structure 72. For the positions of the first dielectric structure 71 and the second dielectric structure 72, reference may be made to those in the embodiments shown in FIG. 10 to FIG. 13 described above, and the positions will not be described in detail here. The difference lies in that, in this embodiment, the first dielectric structure 71 and the second dielectric structure 72 are different in thickness.

When the thickness of the dielectric structure 7 varies, the dielectric constant temperature coefficient of the dielectric between the capacitor plates may also be changed. In a case where the thickness of the dielectric structure 7 is large, the volume ratio (or mass ratio) of the dielectric material with a high dielectric constant temperature coefficient between the two plates of the capacitor structure increases, so that the greater the increase in the dielectric constant of the dielectric with the increase in temperature, the greater the capacitance of the capacitor structure when the temperature increases, and vice versa, the lesser the capacitance of the capacitor structure with a small thickness of the dielectric structure 7 when the temperature increases.

Therefore, in this embodiment, the thickness of the first dielectric structure 71 and the thickness of the second dielectric structure 72 can be set to be different, so as to achieve the differentiated design of the capacitance of the first capacitor structure 11 and the capacitance of the second capacitor structure 12.

For example, in some other embodiments, the dielectric structure 7 can still include the first dielectric structure 71 and the second dielectric structure 72. For the positions of the first dielectric structure 71 and the second dielectric structure 72, reference may be made to those in the embodiments shown in FIG. 10 to FIG. 13 described above, and the positions will not be described in detail here. The difference lies in that, in this embodiment, the dielectric constant temperature coefficient of material of the first dielectric structure 71 and the dielectric constant temperature coefficient of material of the second dielectric structure 72 are not equal to each other.

The larger the dielectric constant temperature coefficient of the dielectric structure 7, the larger the dielectric constant temperature coefficient of the dielectric between the two plates of the capacitor structure, so that the greater the increase in the dielectric constant of the dielectric with the increase in temperature, the greater the capacitance of the capacitor structure when the temperature increases, and vice versa, the lesser the capacitance of the capacitor structure. Therefore, in this embodiment, the dielectric constant temperature coefficients of the first dielectric structure 71 and the second dielectric structure 72 can be set to be different, so as to achieve the differentiated design of capacitances of the first capacitor structure 11 and the second capacitor structure 12.

In some optional embodiments, under the same driving current, the luminance of light emitted by the first color light-emitting element 61 is less than the luminance of light emitted by the second color light-emitting element 62; the capacitance of the first capacitor structure 11 is greater than the capacitance of the second capacitor structure 12.

In an embodiment, under the same driving current, the luminance of light emitted by different color light-emitting elements 6 can reflect the efficiencies of light emitted by the light-emitting elements 6. Under the same driving current, the luminance of light emitted by the first color light-emitting element 61 is less than the luminance of light emitted by the second color light-emitting element 62, indicating that the efficiency of light emitted by the first color light-emitting element 61 is lower than the efficiency of light emitted by the second color. The driving current provided by the first pixel circuit 31 to the first color light-emitting element 61 can be defined as a first driving current, and the driving current provided by the second pixel circuit 32 to the second color light-emitting element 62 can be defined as a second driving current. When the required luminance of light emitted by the first color light-emitting element 61 and the required luminance of light emitted by the second color light-emitting element 62 are the same, the first driving current should be greater than the second driving current.

In this way, during at least part of the display period of the display panel, the first driving current transmitted by the first pixel circuit 31 to the first sub-electrode 601 is greater than the second driving current transmitted by the second pixel circuit 32 to the second sub-electrode 602, that is, the driving transistor in the first pixel circuit 31 is required to generate a larger driving current. With this setting, the driving transistor in the first pixel circuit 31 is more sensitive to temperature changes, which may cause the driving current output by the first pixel circuit 31 to increase more in a high temperature environment, thereby causing the luminance of light emitted by the first color light-emitting element 61 to be too large, and the color of the image displayed to be deviated toward the first color.

Based on this, in this embodiment, the capacitance of the first capacitor structure 11 can be set to be greater than the capacitance of the second capacitor structure 12, so that the first capacitor structure 11 can store more charges, and absorb more driving current, thereby ensuring the stability of the driving current received by the first sub-electrode 601, and solving the color deviation problem.

In an embodiment, as shown in FIG. 11 and FIG. 12, in some embodiments, an overlapping area S1 of projections of the first dielectric structure 71 and the first sub-electrode 601 can be set to be greater than an overlapping area S2 of projections of the second dielectric structure 72 and the second sub-electrode 602, that is, S1>S2, so that the capacitance of the first capacitor structure 11 is greater than the capacitance of the second capacitor structure 12.

As shown in FIG. 14, in other embodiments, a thickness d1 of the first dielectric structure 71 can be set to be greater than a thickness d2 of the second dielectric structure 72, so that the capacitance of the first capacitor structure 11 is greater than the capacitance of the second capacitor structure 12.

In some other embodiments, the dielectric constant temperature coefficient of material of the first dielectric structure 71 can be set to be greater than the dielectric constant temperature coefficient of material of the second dielectric structure 72, so that the capacitance of the first capacitor structure 11 is greater than the capacitance of the second capacitor structure 12.

In addition, in the embodiments shown in FIG. 10 to FIG. 14 described above, the differentiated design of the first capacitor structure 11 and the second capacitor structure 12 is achieved by changing parameters of the first dielectric structure 71 and the second dielectric structure 72, the shapes of the first signal sub-wire 411 and the second signal sub-wire 412 can be the same, and/or the shapes of the first sub-electrode 601 and the second sub-electrode 602 can be the same, thereby reducing the design difficulty of the first signal wire 41 and the first electrode 60.

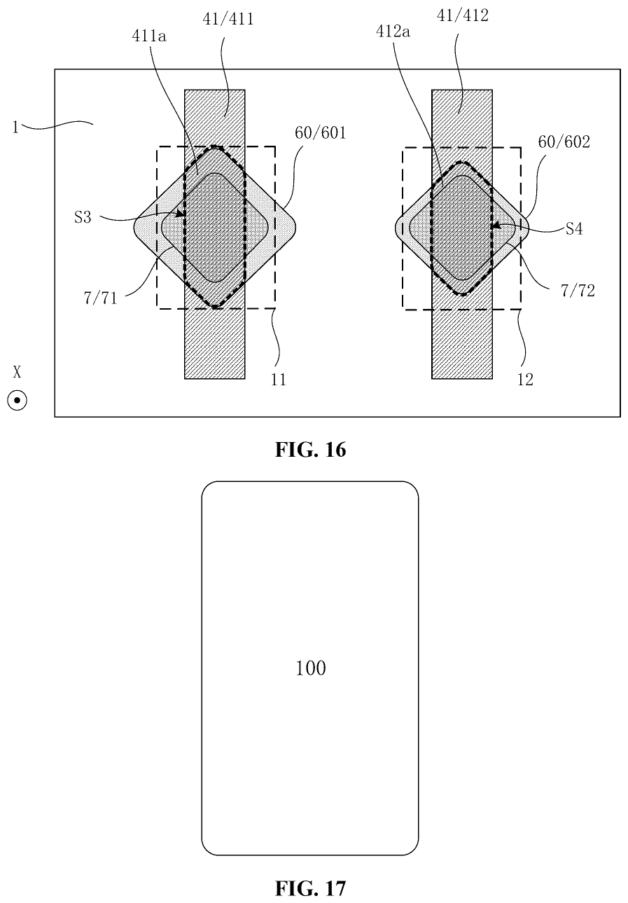

Optionally, FIG. 15 is a schematic diagram of a partial structure of yet another display panel provided in an embodiment of the present disclosure, and FIG. 16 is a schematic diagram of a partial structure of yet another display panel provided in an embodiment of the present disclosure. Referring to FIG. 15 and FIG. 16, in some other embodiments, in the first direction X, an overlapping area of projections of the first signal sub-wire 411 and the first sub-electrode 601 is S3, and an overlapping area of projections of the second signal sub-wire 412 and the second sub-electrode 602 is S4, and S3≠S4.

In an embodiment, as described above, the overlapping area of the two plates of the capacitor structure is the facing area of the plates of the capacitor structure, and the facing area of the plates affects the magnitude of the capacitance. Therefore, in this embodiment, an overlapping area S3 of projections of the first signal sub-wire 411 and the first sub-electrode 601 may be set to be different from an overlapping area S4 of projections of the second signal sub-wire 412 and the second sub-electrode 602, and then the differentiated design of magnitudes of the capacitances of the two can be achieved by differentially setting the facing areas of plates of the first capacitor structure 11 and the second capacitor structure 12.

As shown in FIG. 15 and FIG. 16, a portion of the first sub-signal routing line 411 where the first sub-signal routing line 411 overlaps the first sub-electrode 601 is defined as a first sub-wire segment 411a, and the portion of the second sub-signal routing line 412 where the second sub-signal routing line 412 overlaps the second sub-electrode 602 is defined as a second sub-wire segment 412a. The first sub-electrode 601 and the second sub-electrode 602 may be set to have different areas, and/or the first sub-wire segment 411a and the second sub-wire segment 412a may be set to have different areas, so that S3 #S4. FIG. 15 exemplarily shows that the first sub-electrode 601 and the second sub-electrode 602 have the same area, and the first sub-wire segment 411a and the second sub-wire segment 412a have different areas; FIG. 16 shows that the first sub-electrode 601 and the second sub-electrode 602 have different areas, and the first sub-wire segment 411a and the second sub-wire segment 412a have the same area, but the disclosure is not limited thereto practically. In other embodiments not shown, it may also set that the first sub-electrode 601 and the second sub-electrode 602 have different areas and the first sub-line segment 411a and the second sub-line segment 412a have different areas.

Optionally, if the luminance of light emitted by the first color light-emitting element 61 is less than the luminance of light emitted by the second color light-emitting element 62 under the same driving current, the overlapping area S3 of projections of the first signal sub-wire 411 and the first sub-electrode 601 may be set to be greater than the overlapping area S4 of projections of the second signal sub-wire 412 and the second sub-electrode 602, that is, S3>S4, so that the first capacitor structure 11 has a larger facing area of plates, the second capacitor structure 12 has a smaller facing area of plates, and the capacitance of the first capacitor structure 11 is greater than the capacitance of the second capacitor structure 12, and thus the first capacitor structure 11 can store more charge, and absorb more driving current, thereby ensuring the stability of the first sub-electrode 601 receiving the driving current, and improving the color deviation problem.

Optionally, in an embodiment not shown in the present disclosure, the first signal sub-wire 411 and the first sub-electrode 601 have a first spacing d3 therebetween in the first direction X, and the second signal sub-wire 412 and the second sub-electrode 602 have a second spacing d4 therebetween in the first direction X. It is also possible to set d3≠d4 to allow the distances between the plates of the first capacitor structure 11 and the second capacitor structure 12 to be different, thereby realizing the differentiated design of the first capacitor structure 11 and the second capacitor structure 12.

Illustratively, assuming that the luminance of light emitted by the first color light-emitting element 61 is less than the luminance of light emitted by the second color light-emitting element 62 under the same driving current, d3<d4 can be set so that the capacitance of the first capacitor structure 11 is greater than the capacitance of the second capacitor structure 12. The specific principle is shown in the above embodiment and will not be repeated here.

In some embodiments, the first color light-emitting element may be a blue light-emitting element, and the second color light-emitting element may be a red light-emitting element or a green light-emitting element; the capacitance of the first capacitor structure is greater than the capacitance of the second capacitor structure.

In an embodiment, since the service life of the blue light-emitting material is short and its efficiency of light emission is low, in general, a large driving current is used to drive the blue light-emitting element, and a small driving current is used to drive the red light-emitting element and the green light-emitting element. The driving transistor corresponding to the blue light-emitting element is required to provide a larger driving current, and a temperature sensitivity of the driving transistor may be higher than a temperature sensitivity of the driving transistor corresponding to the red light-emitting element (or the green light-emitting element). Therefore, the first color light-emitting element may be a blue light-emitting element, and the second color light-emitting element may be a red light-emitting element or a green light-emitting element. The blue light-emitting element corresponds to the first capacitor structure, and the red light-emitting element or the green light-emitting element corresponds to the second capacitor structure, and the first capacitor structure is set to have a large capacitance and the second capacitor structure has a small capacitance.

For the differentiated design solutions of capacitances of the first capacitor structure and the second capacitor structure, reference can be made to any of the above embodiments, which will not be repeated here.

The display panel provided in the embodiment of the present disclosure may further include any structure known to the person skilled in the art, such as an encapsulation layer, etc., but is not limited thereto, and the present disclosure does not repeat or limit this.

Based on the same concept described above, a display device is further provided according to an embodiment of the present disclosure. FIG. 17 is a structural diagram of a display device according to an embodiment of the present disclosure. As shown in FIG. 17, the display device includes a display panel 100 according to any embodiment of the present disclosure, and therefore, the display device according to the embodiment of the present disclosure has corresponding advantageous effects of the display panel according to the embodiments of the present disclosure, and details are not described herein again. Exemplarily, the display device may be a mobile phone, a computer, a smart wearable device (for example, a smart watch), an onboard display device, and other electronic devices, which is not limited in the embodiments of the present disclosure.

It is to be noted that the above are merely preferred embodiments of the present disclosure and technical principles used therein. The person skilled in the art will appreciate that the present disclosure is not limited to the particular embodiments described herein and that various significant changes, readjustments, combinations and substitutions can be made for the person skilled in the art without departing from the scope of protection of the present disclosure. Therefore, while the present disclosure has been described in detail through the above-mentioned embodiments, the present disclosure is not limited to the above-described embodiments and may include more other equivalent embodiments without departing from the concept of the present disclosure. The scope of the present disclosure is determined by the scope of the appended claims.

What is claimed is:

1. A display panel, comprising:
a substrate;
a pixel circuit layer arranged on a side of the substrate, wherein the pixel circuit layer comprises a plurality of pixel circuits and a plurality of signal wires, and the plurality of signal wires comprise at least one first signal wire;
a light-emitting element layer arranged on a side of the pixel circuit layer away from the substrate, wherein the light-emitting element layer comprises a plurality of light-emitting elements, a light-emitting element of the plurality of light-emitting elements comprises a first electrode, and the first electrode is electrically connected to a pixel circuit of the plurality of pixel circuits; and in a first direction, at least one first electrode at least partially overlaps the first signal wire, and the first direction is a thickness direction of the display panel; and
a dielectric structure, wherein in the first direction, the dielectric structure is located between the first signal wire and the first electrode, and at least partially overlaps each of the first signal wire and the first electrode; at a first temperature T1, the dielectric structure has a first dielectric constant ε1, and at a second temperature T2, the dielectric structure has a second dielectric constant ε2, wherein (T1−T2)(ε1−ε2)>0.

2. The display panel according to claim 1, wherein in the first direction, a film layer in which the first electrode is located and a film layer in which the first signal wire is located are spaced apart by an insulating layer, and the dielectric structure at least partially overlaps the insulating layer, and a dielectric constant temperature coefficient of the dielectric structure is greater than a dielectric constant temperature coefficient of the insulating layer.

3. The display panel according to claim 2, wherein the insulating layer comprises a first part, and the first part is located on a side of the dielectric structure away from the substrate.

4. The display panel according to claim 1, wherein the pixel circuit layer comprises a first metal layer, a capacitor metal layer, a second metal layer and a third metal layer arranged in the first direction, and the third metal layer is located between the second metal layer and a film layer in which the first electrode is located; and
the first signal wire is located in at least one of the first metal layer, the capacitor metal layer, the second metal layer or the third metal layer.

5. The display panel according to claim 4, wherein the first signal wire is located in the third metal layer.

6. The display panel according to claim 1, wherein the first signal wire comprises a first power supply voltage signal line, and the first power supply voltage signal line is electrically connected to the pixel circuit and is configured to provide a first power supply voltage signal to the pixel circuit.

7. The display panel according to claim 1, wherein the first signal wire comprises a first wire segment, and in the first direction, a projection of the first wire segment onto the substrate and a projection of the dielectric structure onto the substrate are both located in a projection of the first electrode onto the substrate and the first wire segment at least partially overlaps the dielectric structure.

8. The display panel according to claim 1, wherein the light-emitting element comprises a first color light-emitting element and a second color light-emitting element, a first electrode of the first color light-emitting element is a first sub-electrode, and a first electrode of the second color light-emitting element is a second sub-electrode;
the pixel circuit comprises a first pixel circuit and a second pixel circuit, the first pixel circuit is electrically connected to the first sub-electrode, and the second pixel circuit is electrically connected to the second sub-electrode;
the first signal wire comprises a first signal sub-wire and a second signal sub-wire, and in the first direction, the first signal sub-wire at least partially overlaps the first sub-electrode, and the second signal sub-wire at least partially overlaps the second sub-electrode; and the first signal sub-wire and the first sub-electrode whose projections overlap constitute a first capacitor structure, and the second signal sub-wire and the second sub-electrode whose projections overlap constitute a second capacitor structure; and
a magnitude of capacitance of the first capacitor structure is not equal to a magnitude of capacitance of the second capacitor structure.

9. The display panel according to claim 8, wherein the dielectric structure comprises a first dielectric structure and a second dielectric structure; in the first direction, the first dielectric structure is located between the first signal sub-wire and the first sub-electrode, and the first dielectric structure at least partially overlaps the first signal sub-wire and the first sub-electrode; and the second dielectric structure is located between the second signal sub-wire and the second sub-electrode, and the second dielectric structure at least partially overlaps each of the second signal sub-wire and the second sub-electrode; and
in the first direction, an overlapping area between a projection of the first dielectric structure and a projection of the first sub-electrode is S1, and an overlapping area between a projection of the second dielectric structure and a projection of the second sub-electrode is S2, and S1≠S2.

10. The display panel according to claim 9, wherein under a same driving current, luminance of light emitted by the first color light-emitting element is less than luminance of light emitted by the second color light-emitting element; and
S1>S2.

11. The display panel according to claim 8, wherein the dielectric structure comprises a first dielectric structure and a second dielectric structure; in the first direction, the first dielectric structure is located between the first signal sub-wire and the first sub-electrode, and the first dielectric structure at least partially overlaps the first signal sub-wire and the first sub-electrode; and the second dielectric structure is located between the second signal sub-wire and the second sub-electrode, and the second dielectric structure at least partially overlaps the second signal sub-wire and the second sub-electrode; and
thicknesses of the first dielectric structure and the second dielectric structure are different.

12. The display panel according to claim 11, wherein under a same driving current, luminance of light emitted by the first color light-emitting element is less than luminance of light emitted by the second color light-emitting element; and
the thickness of the first dielectric structure is greater than the thickness of the second dielectric structure.

13. The display panel according to claim 8, wherein the dielectric structure comprises a first dielectric structure and a second dielectric structure; in the first direction, the first dielectric structure is located between the first signal sub-wire and the first sub-electrode, and the first dielectric structure at least partially overlaps the first signal sub-wire and the first sub-electrode; and the second dielectric structure is located between the second signal sub-wire and the second sub-electrode, and the second dielectric structure at least partially overlaps the second signal sub-wire and the second sub-electrode; and
a dielectric constant temperature coefficient of material of the first dielectric structure and a dielectric constant temperature coefficient of material of the second dielectric structure are not equal to each other.

14. The display panel according to claim 13, wherein under a same driving current, luminance of light emitted by the first color light-emitting element is less than luminance of light emitted by the second color light-emitting element; and
the dielectric constant temperature coefficient of material of the first dielectric structure is greater than the dielectric constant temperature coefficient of material of the second dielectric structure.

15. The display panel according to claim 8, wherein in the first direction, an overlapping area of a projection of the first signal sub-wire and a projection of the first sub-electrode is S3, and an overlapping area of a projection of the second signal sub-wire and a projection of the second sub-electrode is S4, and S3≠S4.

16. The display panel according to claim 15, wherein under a same driving current, luminance of light emitted by the first color light-emitting element is less than luminance of light emitted by the second color light-emitting element; and
S3>S4.

17. The display panel according to claim 8, wherein the first color light-emitting element is a blue light-emitting element, and the second color light-emitting element is a red light-emitting element or a green light-emitting element; and
the capacitance of the first capacitor structure is greater than the capacitance of the second capacitor structure.

18. A display device, comprising a display panel, wherein the display panel comprises:
a substrate;
a pixel circuit layer arranged on a side of the substrate, wherein the pixel circuit layer comprises a plurality of pixel circuits and a plurality of signal wires, and the plurality of signal wires comprise at least one first signal wire;
a light-emitting element layer arranged on a side of the pixel circuit layer away from the substrate, wherein the light-emitting element layer comprises a plurality of light-emitting elements, a light-emitting element of the plurality of light-emitting elements comprises a first electrode, and the first electrode is electrically connected to a pixel circuit of the plurality of pixel circuits; and in a first direction, at least one first electrode at least partially overlaps the first signal wire, and the first direction is a thickness direction of the display panel; and
a dielectric structure, wherein in the first direction, the dielectric structure is located between the first signal wire and the first electrode, and at least partially overlaps each of the first signal wire and the first electrode; at a first temperature T1, the dielectric structure has a first dielectric constant ε1, and at a second temperature T2, the dielectric structure has a second dielectric constant ε2, wherein (T1−T2)(ε1−ε2)>0.
